(19) United States
(12) Patent Application Publication
(10) Pub. No.: US 2025/0331348 A1
(43) Pub. Date: Oct. 23, 2025

(54) DISPLAY DEVICE AND MANUFACTURING METHOD THEREOF

(71) Applicant: Samsung Display Co., LTD., Yongin-si (KR)

(72) Inventors: Hyun Seok KIM, Yongin-si (KR); Seung Jun YU, Yongin-si (KR); Shin Tack KANG, Yongin-si (KR)

(21) Appl. No.: 18/959,287

(22) Filed: Nov. 25, 2024

(30) Foreign Application Priority Data
Apr. 22, 2024 (KR) 10-2024-0053389

(51) Int. Cl. H10H 29/32; H10H 29/01; H10H 29/37; H10H 29/85; H10H 29/852

(52) U.S. Cl. CPC H10H 29/32; H10H 29/012; H10H 29/0361; H10H 29/0362; H10H 29/37; H10H 29/8517; H10H 29/852

(57) ABSTRACT

A display device includes a substrate including a first surface, a second surface, and a side surface between the first surface and the second surface, a pixel circuit layer on the first surface and the side surface of the substrate and including a transistor, and a light emitting element on the pixel circuit layer and electrically connected to the transistor, wherein the side surface of the substrate has an inclination.

### CROSS-REFERENCE TO RELATED APPLICATION

The present application claims priority to and the benefit of Korean Patent Application No. 10-2024-0053389, filed on Apr. 22, 2024, in the Korean Intellectual Property Office, the entire disclosure of which is incorporated herein by reference.

### BACKGROUND

### 1. Field

Aspects of the present disclosure relate to a display device and a manufacturing method thereof.

### 2. Description of the Related Art

Recently, as interest in information display is increasing, significant advancements have been made in the field of display devices. This surge in interest has driven extensive research and development efforts aimed at enhancing the performance, efficiency, and versatility of display technologies.

The above information disclosed in this Background section is only for enhancement of understanding of the background of the invention and therefore it may contain information that does not form the prior art.

### SUMMARY

Aspects of embodiments of the present disclosure are directed to a manufacturing method that can improve impact strength of a display device.

The object of the present invention is not limited to the aforesaid, but other objects not described herein will be clearly understood by those skilled in the art from descriptions below.

According to some embodiments of the present disclosure, there is provided a display device including: a substrate including a first surface, a second surface, and a side surface between the first surface and the second surface; a pixel circuit layer on the first surface and the side surface of the substrate and including a transistor; and a light emitting element on the pixel circuit layer and electrically connected to the transistor, wherein the side surface of the substrate has an inclination.

In some embodiments, the transistor includes a first conductive layer, a second conductive layer, and an insulating layer between the first conductive layer and the second conductive layer, and the insulating layer is on the side surface of the substrate.

In some embodiments, the insulating layer has an inclination on the side surface of the substrate.

In some embodiments, the display device further includes: an encapsulation layer on the light emitting element, wherein the encapsulation layer is on the side surface of the substrate.

In some embodiments, the encapsulation layer has an inclination on the side surface of the substrate.

In some embodiments, the display device further includes: a bank on the encapsulation layer.

In some embodiments, the display device further includes: a light conversion pattern within an opening of the bank.

In some embodiments, the light conversion pattern is directly on the encapsulation layer.

In some embodiments, the display device further includes: a color filter on the light conversion pattern.

In some embodiments, the display device further includes: a rotating member configured to wind and unfold the substrate.

In some embodiments, the display device further includes: a housing configured to accommodate the substrate and the rotating member.

1 According to some embodiments of the present disclosure, there is provided a manufacturing method of a display device including: forming a trench on a first surface of a substrate; forming a pixel circuit layer on the trench; forming a light emitting element on the pixel circuit layer; forming a cutting line on a lower surface of the trench; and etching a second surface of the substrate to reduce a thickness of the substrate.

In some embodiments, the pixel circuit layer has an inclination on a side surface of the trench.

In some embodiments, the manufacturing method further includes: forming an encapsulation layer on the light emitting element, wherein the encapsulation layer is formed on the trench.

In some embodiments, the encapsulation layer has an inclination on a side surface of the trench.

In some embodiments, the manufacturing method further includes: forming a light conversion pattern on the encapsulation layer.

In some embodiments, the manufacturing method further including: forming a color filter on the light conversion pattern.

In some embodiments, a depth of the trench is 80 μm to 100 μm.

In some embodiments, a depth of the cutting line is 16 μm to 20 μm.

In some embodiments, the substrate is cut along the cutting line in the etching the second surface of the substrate.

Specific details of other embodiments are included in the specification and drawings.

Thus, according to some embodiments, by forming a trench in the substrate, an etchant contact time may be reduced (e.g., minimized) in a process of etching the substrate, thereby improving an impact strength of the substrate.

Effects according to some embodiments are not limited by contents exemplified above, and more various effects are included in the present specification.

### BRIEF DESCRIPTION OF THE DRAWINGS

Non-limiting and non-exhaustive embodiments according to the present disclosure are described with reference to the following figures, wherein like reference numerals refer to like parts throughout the various views unless otherwise specified.

FIG. 1 is a perspective view schematically showing a display device according to some embodiments of the present disclosure.

FIG. 2 is a side perspective view schematically showing a display device according to some embodiments of the present disclosure.

FIG. 3 is a perspective view showing a display module in an unfolded state in a display device according to some embodiments of the present disclosure.

FIG. 4 is a plan view schematically showing a display device according to some embodiments of the present disclosure.

FIG. 5 is a circuit diagram schematically showing an electrical connection relationship of sub-pixels according to some embodiments of the present disclosure.

FIG. 6 is a plan view schematically showing a pixel according to some embodiments of the present disclosure.

FIG. 7 is a cross-sectional view taken along the line A-A′ of FIG. 6, according to some embodiments of the present disclosure.

FIG. 8 is a cross-sectional view schematically showing a non-display area of a display module according to some embodiments of the present disclosure.

FIGS. 9 to 12 are cross-sectional views showing step-by-step processes of a method manufacturing of a display device according to some embodiments of the present disclosure.

### DETAILED DESCRIPTION

Hereinafter, a preferred embodiment according to the present invention will be described in detail with reference to the attached drawings. It should be noted that only the parts necessary to understand the operation according to the present invention will be described in the following description, and the description of other parts will be omitted to not obscure the gist of the present invention. The present invention is not limited to the embodiments described herein and may be embodied in other forms. However, the embodiments described herein are provided to explain in detail enough to enable those skilled in the art to easily implement the technical idea of the present invention.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Here, terms such as first, second, etc. may be used to describe various components, but these components are not limited to these terms. These terms are used only to distinguish one constituent element from another constituent element. Accordingly, the first component may be referred to as the second component within the scope of what is disclosed herein.

Spatially relative terms such as “below,” “above,” etc. may be used for descriptive purposes, thereby describing the relationship of one element or feature to another element(s) or feature(s) as shown in the drawings. do. Spatially relative terms are intended to include different directions in use, operation, and/or manufacture in addition to the directions depicted in the drawings. For example, if the device shown in the drawings is turned over, elements depicted as being disposed “below” other elements or features may be disposed “above” the other elements or features. Accordingly, in some embodiments, the term “below” may include both above and below directions. Additionally, the device may be oriented in other directions (e.g., rotated by 90 degrees or in other orientations), and thus the spatially relative terms used herein should be interpreted accordingly.

Various embodiments are described with reference to drawings that schematize ideal embodiments. Accordingly, it will be expected that the shapes may vary depending, for example, on tolerances and/or manufacturing techniques. Accordingly, embodiments disclosed herein should not be construed as being limited to the specific shapes shown, and should be construed to include changes in shapes that occur, for example, as a result of manufacturing. As such, the shapes shown in the drawings may not depict the actual shapes of areas of the device, and the present embodiments are not limited thereto.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value. Furthermore, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

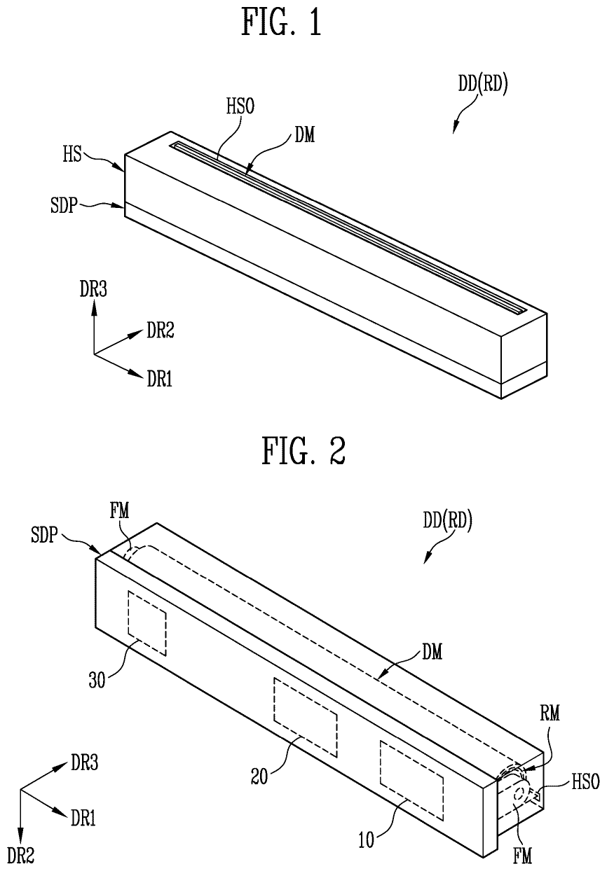

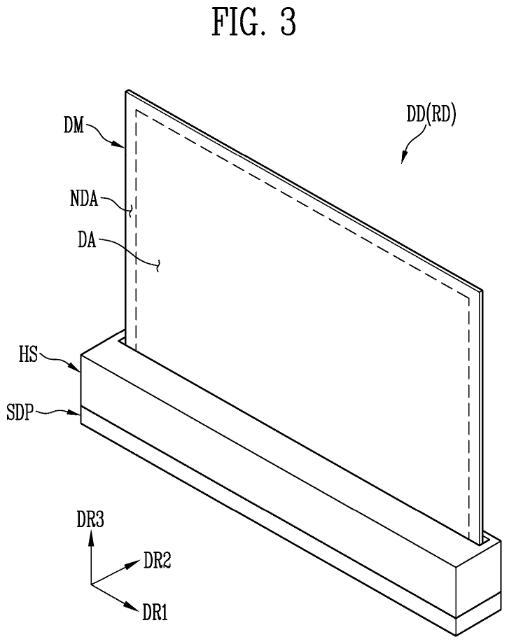

FIG. 1 is a perspective view schematically showing a display device according to some embodiments of the present disclosure. FIG. 2 is a side perspective view schematically showing a display device according to some embodiments of the present disclosure. FIG. 3 is a perspective view showing a display module in an unfolded state in a display device according to some embodiments of the present disclosure.

Referring to FIGS. 1 to 3, a display device DD according to some embodiments may be a rollable display device RD.

The display device DD may include a housing HS and a mounting unit SDP. The display device DD may further include a display module DM (e.g., a display panel), a rotation member RM, and/or a holding member FM provided inside the housing HS.

The housing HS may be a structure that accommodates the display module DM wound with a set or predetermined curvature. The display module DM may be a rollable display module.

A slot HSO (or housing opening) through which the display module DM can pass may be provided on one side surface of the housing HS. The slot HSO of the housing HS may be a passage for winding and unfolding (e.g., unwinding) the display module DM. For example, the display module DM may be wound inside of the housing HS or may be unfolded outside of the housing HS (e.g., in the third direction DR3) through a slot HSO of the housing HS. A shape of the slot HSO of the housing HS may correspond to a cross-sectional shape of the display module DM, but is not limited thereto.

The rotating member RM (e.g., a roller) may be accommodated in the housing HS to wind and/or unfold the display module DM (or display panel). The rotation member RM may be rotatably disposed inside the housing HS. The rotating member RM (e.g., the roller) may be fixed within the housing HS by the holding member FM. The rotation member RM may have a cylindrical shape extending in the first direction DR1, but is not limited thereto. For example, the rotating member RM may have a polygonal cross-sectional shape. The display module DM may be wound around an outer surface of the rotating member RM.

The holding member FM may fix or support the rotating member RM within the housing HS. For example, the holding member FM may be disposed on both ends of the rotating member RM, and rotation axis of the rotating member RM may be rotatably coupled to the holding member FM. The holding member FM can rotate the rotating member RM. For example, the holding member FM may include a motor disposed on at least one side of the rotating member RM, and may rotate the rotating axis using the motor. For example, the motor may be implemented as a stepping motor, thermo motor, or the like.

The mounting unit SDP may be provided on one side of the housing HS. A control unit 30 for outputting images to the display module DM, a power supply unit 20, a speaker for outputting sound, an input/output terminal for inputting or outputting various signals, and a wireless transceiver (e.g., a wireless transmitting and receiving device) capable of transmitting or receiving signals wirelessly may be provided in the mounting unit SDP. Accordingly, various control printed circuit boards constituting the control unit 30 and power supply printed circuit boards constituting the power supply unit 20 may be disposed inside the mounting unit SDP but are not limited thereto. According to some embodiments, a motor control unit 10 for controlling the motor may be provided in the mounting unit SDP.

The display module DM can display an image. The display module DM (e.g., the display panel) may have flexibility. For example, the display module DM may have a curled characteristic. Accordingly, when the display device DD is in a closed mode, the display module DM may be wound and stored inside the housing HS, and when the display device DD is in an open mode, the display module DM may be pulled out (e.g., unwound) in an opposite direction of a winding direction and unfolded in one direction from the housing HS.

The display module DM may be switched from a fully wound state to a fully unfolded state, or from a fully unfolded state to a fully wound state. The fully wound state may mean that the display module DM is stored inside the housing HS and the display device DD does not display an image. According to some embodiments, the display module DM may be switched from a fully wound state to a partially unfolded state. A state in which a part of the display module DM is unfolded may mean a state in which a part of the display module DM extends out of (e.g., is disposed outside) the housing HS.

The display module DM may be provided in various suitable shapes, for example, shapes of a rectangular plate with two pairs of sides parallel to each other but is not limited thereto. When the display module DM is in the shape of the rectangular plate, one pair of sides may be longer than the other pair of sides. In the drawing, the display module DM is shown as having angled corners made of straight lines, but the display module DM is not limited thereto.

The display module DM may include a display area DA that displays an image and a non-display area NDA provided on at least one side of the display area DA. The non-display area NDA may be an area on which the image is not displayed.

According to some embodiments, the display module DM may include a sensing area and a non-sensing area. The display module DM may not only display an image through the sensing area, but may also sense a touch input made on a display surface (e.g., an input surface) or sense light incident from the front. The non-sensing area may surround the sensing area, but this is exemplary and is not limited thereto. According to some embodiments, some areas of the display area DA may correspond to the sensing area.

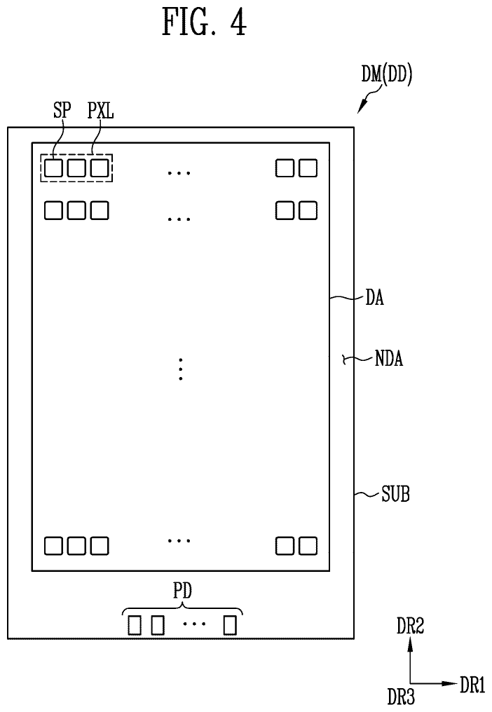

FIG. 4 is a plan view schematically showing a display device according to some embodiments of the present disclosure.

For convenience of description, FIG. 4 briefly shows the structure of the display device DD, for example, the display module DM provided in the display device DD, centering on the display area DA where an image is displayed.

Referring to FIG. 4, the display module DM may include a display area DA and a non-display area NDA. The display module DM may include a substrate SUB, sub-pixels SP, and pads PD.

The substrate SUB may include a transparent insulation material and transmit light. The substrate SUB may have flexibility. For example, the substrate SUB may be one of a film substrate containing a polymer organic material and a plastic substrate. The substrate SUB may include at least one of polystyrene, polyvinyl alcohol, polymethyl methacrylate, polyether sulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

Sub-pixels SP (or pixels PXL) may be disposed in the display area DA of the substrate SUB. The display area DA may have various suitable shapes. For example, the display area DA may have various suitable shapes such as a closed polygon with sides as straight lines, a circle, an ellipse, or any other curved shape with sides that may include a curved line, a semicircle, a semi-ellipse, and/or a straight line.

The non-display area NDA may be provided on at least one side of the display area DA. For example, the non-display area NDA may surround an edge of the display area DA. The sub-pixels SP may be arranged in a matrix form in the first direction DR1 and the second direction DR2 intersecting the first direction DR1 on the substrate SUB, but the arrangement form of the sub-pixels SP is not limited thereto. For example, the sub-pixels SP may be arranged in a zigzag shape along the first direction DR1 and the second direction DR2. For example, the first direction DR1 may be a row direction, and the second direction DR2 may be a column direction. Two or more sub-pixels SP among the sub-pixels SP may constitute one pixel PXL, but the present invention is not limited thereto.

Components for controlling the sub-pixels SP may be disposed in the non-display area NDA. For example, lines electrically connected to the sub-pixels SP may be disposed in the non-display area NDA. The lines may include, for example, gate lines, data lines, and the like.

A driver electrically connected to the sub-pixels SP may be disposed (e.g., integrated) in the non-display area NDA of the display module DM to drive the sub-pixels SP. Additionally, pads PD may be disposed in the non-display area NDA. The pads PD may be electrically connected to the sub-pixels SP through lines. For example, the pads PD may be electrically connected to the sub-pixels SP through data lines.

In some embodiments, the circuit board may be electrically connected to the pads PD using a conductive adhesive member such as an anisotropic conductive film. The circuit board may be a flexible circuit board or a flexible film made of a flexible material. The driver may be mounted on the circuit board and electrically connected to the pads PD.

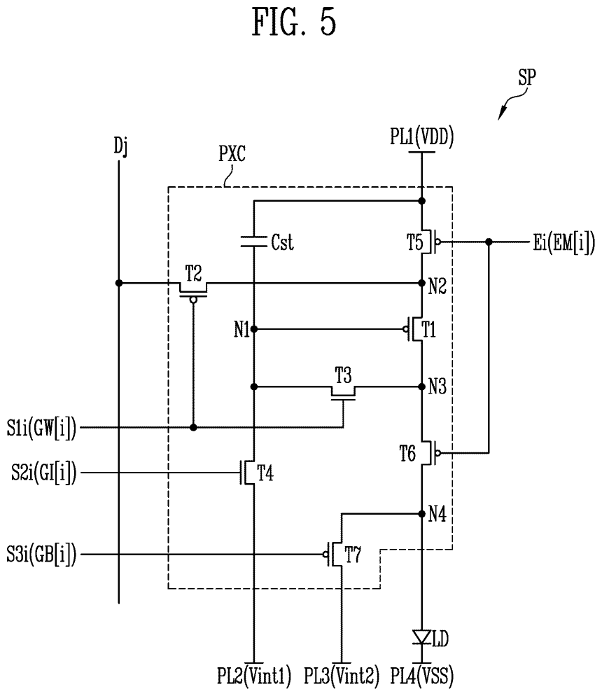

FIG. 5 is a circuit diagram schematically showing an electrical connection relationship of sub-pixels according to some embodiments of the present disclosure.

For convenience of description, FIG. 5 shows a sub-pixel SP disposed on the i-th horizontal line (e.g., the i-th pixel row) and connected to the j-th data line Dj.

The sub-pixel SP may be disposed on the i-th horizontal line (e.g., the i-th pixel row). The sub-pixel SP may include a pixel circuit PXC and a light emitting element LD. The pixel circuit PXC may include first to seventh transistors T1, T2, T3, T4, T5, T6, and T7 and a storage capacitor Cst.

The first electrode of the light emitting element LD may be electrically connected to the fourth node N4, and the second electrode of the light emitting element LD may be electrically connected to the fourth power line PL4. The light emitting element LD may generate light with a set or predetermined luminance in response to an amount of current (e.g., driving current) supplied from the first transistor T1. In some embodiments, the light emitting element LD may be an organic light emitting diode including an organic emission layer.

The first transistor T1 (e.g., the driving transistor) may be electrically connected between the first power line PL1 and the first electrode of the light emitting element LD. The first transistor T1 may include a gate electrode electrically connected to the first node N1. The first transistor T1 may control the amount of current (e.g., driving current) flowing from the first power line PL1 to the fourth power line PL4 via the light emitting element LD based on a voltage of the first node N1. The first power voltage VDD may be applied to the first power line PL1, the second power voltage VSS may be applied to the fourth power line PL4, and the first power voltage VDD may be set to a higher voltage than the second power voltage VSS.

The second transistor T2 may be electrically connected between the j-th data line Dj and the second node N2. A gate electrode of the second transistor T2 may be electrically connected to the 1i-th scan line S1i (e.g., the first scan line). The second transistor T2 may be turned on when the first scan signal GW[i] (e.g., the low-level first scan signal) is supplied to the 1i-th scan line S1i to electrically connect the j-th data line Dj and the second node N2. When each of the first transistor T1 and the third transistor T3 is in a turn-on state, the second transistor T2 may transfer a data signal of the j-th data line Dj to the second node N2 in response to the first scan signal GW[i].

The third transistor T3 may be electrically connected between the first node N1 and the third node N3. A gate electrode of the third transistor T3 may be electrically connected to the 1i-th scan line S1i. A gate electrode of the third transistor T3 may be electrically connected to the 1i-th scan line S1i. The third transistor T3 may be turned on when the first scan signal GW[i] is supplied to the 1i-th scan line S1i. When the third transistor T3 is turned on, the first transistor T1 may become diode-connected (e.g., have a diode-connected form).

The fourth transistor T4 may be electrically connected between the first node N1 and the second power line PL2. A gate electrode of the fourth transistor T4 may be electrically connected to the 2i-th scan line S2i (e.g., the second scan line). The first initialization power voltage Vint1 may be applied to the second power line PL2. The fourth transistor T4 may be turned on by the second scan signal GI [i]. When the fourth transistor T4 is turned on, the first initialization power voltage Vint1 may be supplied to the first node N1 (i.e., gate electrode of the first transistor T1).

The fifth transistor T5 may be electrically connected between the first power line PL1 and the second node N2. A gate electrode of the fifth transistor T5 may be electrically connected to the i-th emission control line Ei (e.g., the emission control line). The sixth transistor T6 may be electrically connected between the third node N3 and the light emitting element LD (e.g., the fourth node N4). A gate electrode of the sixth transistor T6 may be electrically connected to the i-th emission control line Ei. The fifth transistor T5 and the sixth transistor T6 may be turned off when the i-th emission control signal EM[i] (e.g., high level emission control signal EM[i]) is supplied to the i-th emission control line Ei, and may be turned on in other cases.

The seventh transistor T7 may be electrically connected between the first electrode (i.e., fourth node N4) of the light emitting element LD and the third power line PL3. A gate electrode of the seventh transistor T7 may be electrically connected to the 3i-th scan line S3i. A second initialization power supply voltage Vint2 may be applied to the third power line PL3. According to some embodiments, the second initialization power voltage Vint2 may be the same as or different from the first initialization power voltage Vint1. The seventh transistor T7 may be turned on by the third scan signal GB[i] supplied to the 3i-th scan line S3i to supply the first electrode of the light emitting element LD the second initialization power voltage Vint2.

The storage capacitor Cst may be connected or formed between the first power line PL1 and the first node N1.

In some embodiments, the pixel circuit PXC may include a P-type transistor and an N-type transistor. The third transistor T3 and the fourth transistor T4 may be formed as oxide transistors including an oxide semiconductor. For example, the third transistor T3 and the fourth transistor T4 may be N-type oxide semiconductor transistors and may include an oxide semiconductor layer as an active layer, but are not limited thereto. The oxide semiconductor transistor may be processed at a low temperature and may have a lower charge mobility than the polysilicon semiconductor transistor. That is, because the oxide semiconductor transistor can have excellent off-current characteristics, leakage current in the third transistor T3 and fourth transistor T4 can be reduced (e.g., minimized).

Transistors (e.g., the first, second, fifth, sixth, and seventh transistors T1, T2, T5, T6, and T7) other than the third and fourth transistors T3 and T4, may be formed of a polysilicon transistor containing a silicon semiconductor, and may include a polysilicon semiconductor layer as an active layer. For example, the active layer may be formed through a low-temperature poly-silicon (LTPS) process. For example, the polysilicon transistor may be a P-type polysilicon transistor. Because the polysilicon semiconductor transistor has a fast response speed, it can be used as (e.g., applied to) a switching element requiring fast switching.

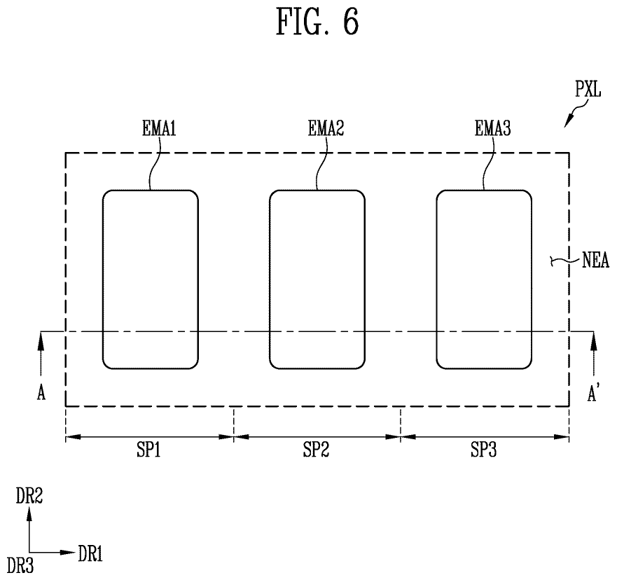

FIG. 6 is a plan view schematically showing a pixel according to some embodiments of the present disclosure.

Referring to FIG. 6, the pixel PXL may include a first sub-pixel SP1, a second sub-pixel SP2, and/or a third sub-pixel SP3 arranged in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA. The third sub-pixel SP3 may include a third emission area EMA3 and a non-emission area NEA around the third emission area EMA3.

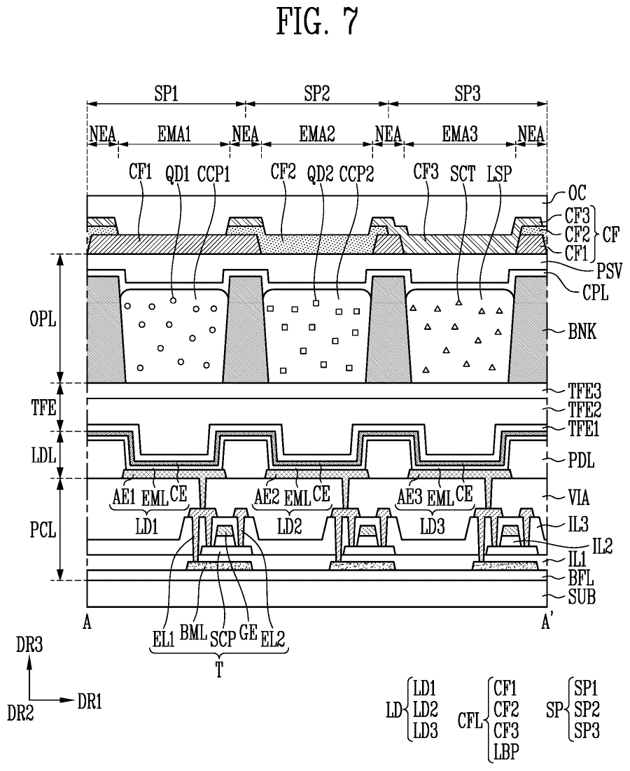

The first emission area EMA1 may be an area where light is emitted from the first light emitting element (e.g., LD1 in FIG. 7) disposed in the first sub-pixel SP1. The second emission area EMA2 may be an area where light is emitted from the second light emitting element (e.g., LD2 in FIG. 7) disposed in the second sub-pixel SP2. The third emission area EMA3 may be an area where light is emitted from the third light emitting element (e.g., LD3 in FIG. 7) disposed in the third sub-pixel SP3.

The first sub-pixel SP1, the second sub-pixel SP2, and/or the third sub-pixel SP3 may have the same or substantially the same area, but are not limited thereto. According to some embodiments, the second sub-pixel SP2 may have a larger area than the first sub-pixel SP1, and the third sub-pixel SP3 may have a larger area than the second sub-pixel SP2.

The first sub-pixel SP1, the second sub-pixel SP2, and/or the third sub-pixel SP3 may have a polygonal shape. For example, the first sub-pixel SP1, the second sub-pixel SP2, and/or the third sub-pixel SP3 may have a square shape or a hexagonal shape, but are not limited thereto. According to some embodiments, the first sub-pixel SP1, the second sub-pixel SP2, and/or the third sub-pixel SP3 may have a circular shape, a semi-elliptical shape, or the like.

The arrangement of sub-pixels shown in FIG. 6 is illustrative and is not necessarily limited thereto. Each pixel PXL may include two or more sub-pixels, the sub-pixels may be arranged in various suitable ways, each of the sub-pixels may have various suitable shapes, and each of the emission areas of the sub-pixels may also have various suitable shapes.

FIG. 7 is a cross-sectional view taken along the line A-A′ of FIG. 6, according to some embodiments of the present disclosure.

In FIG. 7, for convenience of description, the cross-sectional structure (e.g., the stacked structure) may be briefly shown centering on the sub-pixels SP, and the thickness direction of the substrate SUB may be indicated as the third direction DR3.

Referring to FIG. 7, the pixel circuit layer PCL may be disposed on the substrate SUB. The pixel circuit layer PCL may include a buffer layer BFL, a first interlayer insulating layer IL1, a second interlayer insulating layer IL2, a third interlayer insulating layer IL3, a via layer VIA, and/or transistors T.

The buffer layer BFL may be disposed entirely on the substrate SUB. The buffer layer BFL can prevent or substantially impede impurities from diffusing into circuit elements (e.g., driving elements) constituting the pixel circuit (e.g., PXC in FIG. 5), for example, transistors T. The buffer layer BF may be an inorganic insulating layer containing one or more inorganic materials.

The buffer layer BFL may include at least one of silicon nitride (SiNx), silicon oxide (SiOx), silicon oxynitride (SiOxNy), and aluminum oxide (AlOx). The buffer layer BFL may be provided as a single layer, but may also be provided as a multiple layer having at least a double layer. When the buffer layer BFL is provided as multilayers, each of the multilayers may be formed of the same material or different materials. The buffer layer BFL may be omitted depending on materials and process conditions of the substrate SUB.

The first interlayer insulating layer IL1 may be entirely disposed on the buffer layer BFL. The first interlayer insulating layer IL1 may include the same material as the buffer layer BFL, or may include one or more suitable materials mentioned (or exemplified) as constituent materials of the buffer layer BFL.

The second interlayer insulating layer IL2 may be provided and/or formed entirely on the first interlayer insulating layer IL1. The second interlayer insulating layer IL2 may include the same material as the buffer layer BFL, or may include one or more suitable materials mentioned (or exemplified) as constituent materials of the buffer layer BFL.

The third interlayer insulating layer IL3 may be provided and/or formed entirely on the second interlayer insulating layer IL2. The third interlayer insulating layer IL3 may include the same or substantially the same material as the buffer layer BFL, or may include one or more suitable materials mentioned (or exemplified) as constituent materials of the buffer layer BFL.

The via layer VIA may be provided and/or formed entirely on the third interlayer insulating layer IL3. The via layer VIA may be an inorganic insulating layer containing an inorganic material or an organic insulating layer containing one or more organic materials. The inorganic insulating layer may include, for example, at least one of silicon oxide (SiOx), silicon nitride (SiNx), silicon oxynitride (SiOxNy), and aluminum 1 oxide (AlOx). The organic insulating layer include, for example, at least one of acrylic resin, epoxy resin, phenol resin, polyamide resin, polyimide resin, unsaturated polyester resin, polyphenylene ether resin, polyphenylene sulfide resin, and benzocyclobutene resin. In some embodiments, the via layer VIA may be an organic insulating layer containing an organic material.

The via layer VIA may be partially opened to include a via hole (or opening). The via hole may be a connection point for electrically connecting the pixel circuit PXC and the light emitting element LD of each sub-pixel SP.

Circuit elements (e.g., driving elements) of the sub-pixel SP may be disposed on the pixel circuit layer PCL. For example, the transistor T of the sub-pixel SP may be disposed on the pixel circuit layer PCL. In FIG. 7, for convenience of description, one of the transistors T of each sub-pixel SP is shown, and the remaining circuit elements are omitted.

The transistor T of the sub-pixel SP may include a lower metal pattern BML, a semiconductor pattern SCP, a gate electrode GE, a first terminal EL1, and/or a second terminal EL2.

The lower metal pattern BML may be disposed between the buffer layer BFL and the first interlayer insulating layer IL1. The lower metal pattern BML may be formed of a first conductive layer. The lower metal pattern BML may be electrically connected to the first terminal EL1.

The semiconductor pattern SCP may be disposed between the first interlayer insulating layer IL1 and the second interlayer insulating layer IL2. The semiconductor pattern SCP may be a semiconductor layer made of polysilicon, amorphous silicon, oxide semiconductor, and/or the like. The semiconductor pattern SCP may include an active pattern, a first contact area, and a second contact area. The active pattern, the first contact area, and the second contact area may be composed of a semiconductor layer that is not doped with impurities or is doped with impurities. For example, the first contact area and the second contact area may be composed of a semiconductor layer doped with impurities, and the active pattern may be made of a semiconductor layer that is not doped with impurities.

The active pattern of the semiconductor pattern SCP may be an area that overlaps the gate electrode GE and may be a channel area. The first contact area of the semiconductor pattern SCP may be in contact with one end of the active pattern. The first contact area may be electrically connected to the first terminal EL1. The second contact area of the semiconductor pattern SCP may be in contact with the other end of the active pattern. The second contact area may be electrically connected to the second terminal EL2.

The gate electrode GE may be disposed between the second interlayer insulating layer IL2 and the third interlayer insulating layer IL3. The gate electrode GE may be formed of a second conductive layer. The gate electrode GE may overlap a portion of the semiconductor pattern SCP. For example, the gate electrode GE may overlap the active pattern of the semiconductor pattern SCP.

The first terminal EL1 may be disposed between the third interlayer insulating layer IL3 and the via layer VIA. The first terminal EL1 may be formed of a third conductive layer. The first terminal EL1 may contact the first contact area of the semiconductor pattern SCP through a contact hole penetrating the third interlayer insulating layer IL3.

The second terminal EL2 may be disposed between the third interlayer insulating layer IL3 and the via layer VIA. The second terminal EL2 may be formed of a third conductive layer. The second terminal EL2 may contact the second contact area of the semiconductor pattern SCP through a contact hole penetrating the third interlayer insulating layer IL3.

A light emitting element layer LDL may be disposed on the pixel circuit layer PCL. The light emitting element layer LDL may include a first lower electrode AE1, a second lower electrode AE2, a third lower electrode AE3, a pixel definition layer PDL, an emission layer EML, and/or an upper electrode CE.

On the pixel circuit layer PCL (e.g., via layer VIA), first to third lower electrodes AE1, AE2, and AE3 may be disposed in the first to third sub-pixels SP1, SP2, and SP3, respectively. For example, the first lower electrode AE1 may be disposed on the via layer VIA of the first sub-pixel SP1, the second lower electrode AE2 may be disposed on the via layer VIA of the second sub-pixel SP2, and the third lower electrode AE3 may be disposed on the via layer VIA of the third sub-pixel SP3.

Each of the first to third lower electrodes AE1, AE2, and AE3 may be electrically connected to a circuit element disposed on the pixel circuit layer PCL through a via hole penetrating the via layer VIA. For example, the first lower electrode AE1 may be electrically connected to the transistor T of the first sub-pixel SP1 through the first via hole penetrating the via layer VIA, the second lower electrode AE2 may be electrically connected to the transistor T of the second sub-pixel SP2 through the second via hole penetrating the via layer VIA, and the third lower electrode AE3 may be electrically connected to the transistor T of the third sub-pixel SP3 through the third via hole penetrating the via layer VIA.

In some embodiments, the first to third lower electrodes AE1, AE2, and AE3 may be anode electrodes. Each of the first to third lower electrodes AE1, AE2, and AE3 may have a shape similar to the first to third emission areas EMA1, EMA2, and EMA3 of FIG. 6 in a plane view. For example, the first lower electrode AE1 may have a shape similar to the first emission area EMA1 in a plane view, the second lower electrode AE2 may have a shape similar to the second emission area EMA2 in a plane view, and the third lower electrode AE3 may have a shape similar to the third emission area EMA3 in a plane view, but is not limited thereto.

Each of the first to third lower electrodes AE1, AE2, and AE3 may be electrically connected to the corresponding pixel circuit and receive the driving current. The first to third lower electrodes AE1, AE2, and AE3 may include an opaque conductive material capable of reflecting light, but are not limited thereto. According to some embodiments, the first to third lower electrodes AE1, AE2, and AE3 may include a transparent conductive material.

A pixel definition layer PDL may be disposed on the first to third lower electrodes AE1, AE2, and AE3. The pixel definition layer PDL may include openings that at least partially expose each of the first to third lower electrodes AE1, AE2, and AE3. The pixel definition layer PDL may be a structure that defines (e.g., partitions) the emission area of each of the first to third sub-pixels SP1, SP2, and SP3. For example, the pixel definition layer PDL may define the first emission area EMA1 of the first sub-pixel SP1, the second emission area EMA2 of the second sub-pixel SP2, and the third emission area EMA3 of the third sub-pixel SP3.

The pixel definition layer PDL may be composed of an organic insulating layer containing an organic material. Organic materials may include acrylic resin, epoxy resin, phenol resin, polyamide resin, polyimide resin, and/or the like. According to some embodiments, the pixel definition layer PDL may include a light absorbing material or may be coated with a light absorbing material to absorb light introduced from the outside. For example, the pixel definition layer PDL may include a carbon-based black pigment, but is not necessarily limited thereto.

The emission layer EML may be disposed on the first to third lower electrodes AE1, AE2, and AE3. The emission layer EML may be disposed on the first to third lower electrodes AE1, AE2, and AE3 exposed by openings of the pixel definition layer PDL. The emission layer EML may include a light emitting portion configured to generate light, an electron transport portion configured to transport electrons, and a hole transport portion configured to transport holes, but is not limited thereto. The emission layer EML may be formed through a process such as vacuum deposition or inkjet printing, but is not necessarily limited thereto.

The upper electrode CE may be disposed on the emission layer EML. In some embodiments, the upper electrode CE may be a cathode electrode. The upper electrode CE may be a common layer commonly provided to the first to third sub-pixels SP1, SP2, and SP3. The upper electrode CE may be provided in a plate shape over the entire area of the display area DA. The upper electrode CE may function as a half mirror that partially transmits and partially reflects light emitted from the emission layer EML.

The upper electrode CE may be a thin metal layer having a thickness sufficient to transmit light emitted from the emission layer EML. The upper electrode CE may be formed of a metal material or a transparent conductive material to have a relatively thin thickness. In some embodiments, the upper electrode CE may include at least one of a variety of transparent conductive materials including indium tin oxide, indium zinc oxide, indium tin zinc oxide, aluminum zinc oxide, gallium zinc oxide, zinc tin oxide, or gallium tin oxide. In some other embodiments, the upper electrode CE may include at least one of magnesium, silver, and mixtures thereof. However, the material of the upper electrode CE is not limited to the above-described embodiments.

The first lower electrode AE1, a portion of the emission layer EML that overlaps the first lower electrode AE1, and a portion of the upper electrode CE that overlaps the first lower electrode AE1 may constitute the first light emitting element LD1. The second lower electrode AE2, a portion of the emission layer EML that overlaps the second lower electrode AE2, and a portion of the upper electrode CE that overlaps the second lower electrode AE2 may constitute the second light emitting element LD2. The third lower electrode AE3, a portion of the emission layer EML that overlaps the third lower electrode AE3, and a portion of the upper electrode CE that overlaps the third lower electrode AE3 may constitute the third light emitting element LD3.

The encapsulation layer TFE may be disposed on the light emitting element layer LDL. The encapsulation layer TFE may cover the display element layer DPL. The encapsulation layer TFE may be configured to prevent or substantially impede oxygen and/or moisture from penetrating into the light emitting element layer LDL. The 1 encapsulation layer TFE may include a first encapsulation layer TFE1, a second encapsulation layer TFE2, and a third encapsulation layer TFE3.

The first encapsulation layer TFE1 may be disposed on the upper electrode CE. The second encapsulation layer TFE2 may be disposed on the first encapsulation layer TFE1. The third encapsulation layer TFE3 may be disposed on the second encapsulation layer TFE2. The first encapsulation layer TFE1 may include an inorganic layer. For example, the first encapsulation layer TFE1 may include silicon nitride, silicon oxide, silicon oxynitride, and/or the like. The second encapsulation layer TFE2 may include an organic layer. For example, the second encapsulation layer TFE2 may include an acrylic resin, an epoxy resin, a phenol resin, a polyamide resin, a polyimide resin, an unsaturated polyester resin, a polyphenylene resin, a polyphenylene sulfide resin, a benzocyclobutene, and/or the like. The third encapsulation layer TFE3 may include an inorganic layer. For example, the third encapsulation layer TFE3 may include silicon nitride, silicon oxide, silicon oxynitride, and/or the like. However, the materials of the first to third encapsulation layers TFE1, TFE2, and TFE3 are not necessarily limited thereto.

An optical layer OPL may be disposed on the encapsulation layer TFE. The optical layer OPL may include a bank BNK, a first light conversion pattern CCP1, a second light conversion pattern CCP2, a light scattering pattern LSP, a capping layer CPL, and/or a protective layer PSV.

The bank BNK may be disposed in the non-emissive area NEA on the encapsulation layer TFE. The bank BNK may be disposed directly on the encapsulation layer TFE. The bank BNK may include at least one light blocking material. Accordingly, the bank BNK can prevent or substantially reduce light leakage defects in which light leaks between adjacent sub-pixels SP. According to some embodiments, the bank BNK may include at least one reflective material. Accordingly, the bank BNK may guide the light emitted from each of the first light conversion pattern CCP1, the second light conversion pattern CCP2, and the light scattering pattern LSP 1 to an image display direction of the display device, thereby improving light emission efficiency the sub-pixel SP. According to some embodiments, a reflective material layer may be separately provided and/or formed on the bank BNK to further improve the efficiency of light emitted from each sub-pixel SP. According to some embodiments, the bank BNK may include a transparent material. For example, the bank BNK may include polyamide-based resin, polyimide-based resin, and/or the like, but is not limited thereto.

The bank BNK may include openings that overlap the first to third sub-pixels SP1, SP2, and SP3. The openings of the bank BNK may overlap (e.g., in a plan view) the first to third emission areas EMA1, EMA2, and EMA3, respectively.

The first light conversion pattern CCP1 may be disposed within the opening of the bank BNK of the first sub-pixel SP1. The first light conversion pattern CCP1 may be directly disposed on the encapsulation layer TFE. The first light conversion pattern CCP1 may overlap the first light emitting element LD1 in the third direction DR3. The first light conversion pattern CCP1 may include a plurality of first light conversion particles QD1 dispersed in a set or predetermined matrix material such as a base resin. For example, the first light conversion particles QD1 may be red quantum dots that absorb incident blue light and shift the wavelength according to energy transition to emit red light. In this case, the first sub-pixel SP1 may be a red sub-pixel. The first light conversion pattern CCP1 may be disposed at least in the first emission area EMA1.

The second light conversion pattern CCP2 may be disposed within the opening of the bank BNK of the second sub-pixel SP2. The second light conversion pattern CCP2 may be directly disposed on the encapsulation layer TFE. The second light conversion pattern CCP2 may overlap the second light emitting element LD2 in the third direction DR3. The second light conversion pattern CCP2 may include a plurality of second light conversion particles QD2 dispersed in a set or predetermined matrix material such as a base resin. For example, the second light conversion 1 particles QD2 may be green quantum dots that absorb incident blue light and shift the wavelength according to energy transition to emit green light. In this case, the second sub-pixel SP2 may be a red sub-pixel. The second light conversion pattern CCP2 may be disposed at least in the second emission area EMA2.

The light scattering pattern LSP may be disposed within the opening of the bank BNK of the third sub-pixel SP3. The light scattering pattern LSP may be disposed directly on the encapsulation layer TFE. The light scattering pattern LSP may overlap the third light emitting element LD3 in the third direction DR3. The light scattering pattern LSP may include a plurality of light scattering particles (SCT) dispersed in a matrix material such as a base resin. The light scattering pattern LSP may include light scattering particles SCT such as silica, but the constituent material of the light scattering particles SCT is not limited thereto. According to some embodiments, the light scattering pattern LSP composed of a transparent polymer without light scattering particles SCT, may be provided. For example, the light scattering pattern LSP may transmit incident blue light in the image display direction. In this case, the third sub-pixel SP3 may be a blue sub-pixel. The light scattering pattern LSP may be disposed at least in the third emission area EMA3.

The capping layer CPL may be disposed on the bank BNK, the first light conversion pattern CCP1, the second light conversion pattern CCP2, and/or the light scattering pattern LSP. The capping layer CPL may be composed of an inorganic layer (e.g., inorganic insulating layer) containing an inorganic material. For example, the capping layer CPL may include at least one of metal oxides such as silicon nitride (SiNx), silicon oxide (SiOx), silicon oxynitride (SiOxNy), and aluminum oxide (AlOx), but is limited thereto. According to some embodiments, the capping layer CPL may be composed of an organic insulating layer containing an organic material. The capping layer CPL may be disposed on the first light conversion pattern CCP1, the second light conversion pattern CCP2, and/or the light scattering pattern LSP to protect the first light conversion pattern CCP1, the second light conversion pattern CCP2, and/or the 1 light scattering pattern LSP from external moisture, oxygen, and/or the like, thereby improving (e.g., increasing) reliability.

The protective layer PSV may be disposed on the capping layer CPL. The protective layer PSV may flatten steps of the bank BNK, the first light conversion pattern CCP1, the second light conversion pattern CCP2, and/or the light scattering pattern LSP. According to some embodiments, the protective layer PSV may include resin and hollow particles dispersed within the resin. The protective layer PSV may have a refractive index in the range of 1.1 to 1.3, but is not limited thereto. The hollow particles may refer to particles having an empty space on a surface and/or inside an organic or inorganic particle. The hollow particles may be hollow silica particles. The protective layer PSV can change the path of light emitted from the optical layer OPL to the image display direction by using the difference in the refractive index, thereby improving the luminance of front-outgoing light. The low refractive index layer LRL may recycle light (e.g., blue light) that does not react with the first light conversion pattern CCP1 and/or the second light conversion pattern CCP2 to react with the first light conversion pattern CCP1 and/or the second light conversion pattern CCP2, thereby improving the luminance of the outgoing light of the sub-pixel SP.

A color filter layer CFL may be disposed on the optical layer OPL. The color filter layer CFL may include a first color filter CF1, a second color filter CF2, a third color filter CF3, and/or a light blocking pattern LBP. For example, the first color filter CF1 may be a red color filter, the second color filter CF2 may be a green color filter, and the third color filter CF3 may be a blue color filter, but they are not limited thereto.

The first color filter CF1 may overlap the first emission area EMA1 of the first sub-pixel SP1 in the third direction DR3. The second color filter CF2 may overlap the second emission area EMA2 of the second sub-pixel SP2 in the third direction DR3. The third color filter CF3 may overlap the third emission area EMA3 of the third sub-pixel SP3 in the third direction DR3.

The first to third color filters CF1, CF2, and CF3 may be arranged to overlap (e.g., in a plan view) each other in the non-emission area NEA and be used as the light blocking pattern LBP to block light interference between adjacent sub-pixels SP.

An overcoat layer OC may be disposed on the color filter layer CFL. The overcoat layer OC may cover the color filter layer CFL, the optical layer OPL, the encapsulation layer TFE, the light emitting element layer LDL, and/or the pixel circuit layer PCL. The overcoat layer OC may include various materials suitable for protecting lower layers thereof from foreign substances such as dust, moisture, or the like. For example, the overcoat layer OC may include at least one of an inorganic insulating layer and an organic insulating layer. For example, the overcoat layer OC may include epoxy, but is not necessarily limited thereto.

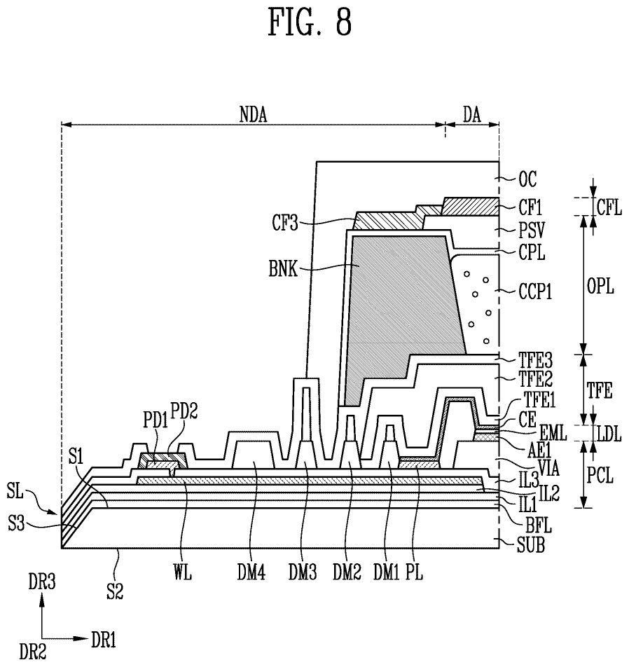

FIG. 8 is a cross-sectional view schematically showing a non-display area of a display module according to some embodiments of the present disclosure.

In FIG. 8, for convenience of description, the cross-sectional structure (e.g., stacked structure) may be briefly shown centering on the non-display area NDA, and the thickness direction of the substrate SUB may be indicated as the third direction DR3.

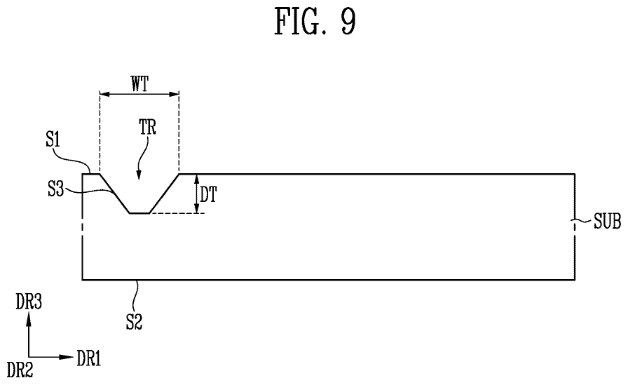

The substrate SUB may include a first surface S1, a second surface S2, and a side surface S3. On the first surface S1 of the substrate SUB, the pixel circuit layer PCL, the light emitting element layer LDL, the encapsulation layer TFE, the optical layer OPL, and/or the color filter layer CFL described above, may be formed. The second surface S2 of the substrate SUB may face the first surface S1. The side surface S3 of the substrate SUB may be disposed between the first surface S1 and the second surface S2. The side surface S3 of the substrate SUB may correspond to an outer edge of the substrate SUB. The side surface S3 of the substrate SUB may have an inclination (e.g., be at an acute angle with respect to a bottom surface of the substrate SUB). In some embodiments, an inclination angle formed between the side surface S3 and the second surface S2 of the substrate SUB may be about 70° to about 80°, but is not necessarily limited thereto. The side surface S3 of the substrate SUB may correspond to the side surface of the trench TR (see, e.g., FIG. 9) formed in the substrate SUB. In this way, by forming the trench TR in the substrate SUB, the contact time of the etchant in the process of etching the substrate SUB can be reduced (e.g., minimized), thereby improving the impact strength of the substrate SUB. A detailed description thereof will be described later with reference to FIG. 9 and the like.

The pixel circuit layer PCL may be disposed on the first surface S1 and the side surface S3 of the substrate SUB. For example, the insulating layers of the pixel circuit layer PCL may be entirely disposed on the first surface S1 of the substrate SUB and may cover the side surface S3 of the substrate SUB. For example, the buffer layer BFL, the first interlayer insulating layer IL1, the second interlayer insulating layer IL2, and/or the third interlayer insulating layer IL3 may be disposed on the side surface S3 of the substrate SUB. The buffer layer BFL, the first interlayer insulating layer IL1, the second interlayer insulating layer IL2, and/or the third interlayer insulating layer IL3 may have an inclination on the side surface S3 of the substrate SUB.

The encapsulation layer TFE may be disposed on the first surface S1 and the side surface S3 of the substrate SUB. For example, the third encapsulation layer TFE3 may be entirely disposed on the first surface S1 of the substrate SUB and may cover the side surface S3 of the substrate SUB. For example, the third encapsulation layer TFE) may be disposed on the side surface S3 of the substrate SUB. The third encapsulation layer TFE3 may have an inclination on the side surface S3 of the substrate SUB. According to some embodiments, the first encapsulation layer TFE1 and/or the capping layer CPL may also be disposed on the side surface S3 of the substrate SUB. In this case, the first encapsulation layer TFE1 and/or the capping layer CPL may have an inclination on the side surface S3 of the substrate SUB.

A power line PL may be disposed in the non-display area NDA. The power line PL may be electrically connected to the upper electrode CE. The power line PL may be disposed on the third interlayer insulating layer IL3. The power line PL may be formed of a third conductive layer. The power line PL may be disposed on the same layer as the first terminal EL1 and/or the second terminal EL2. The power line PL may include the same or substantially the same material as the first terminal EL1 and/or the second terminal EL2. The power line PL may be formed concurrently (e.g., simultaneously) in the same process as the first terminal EL1 and/or the second terminal EL2, but is not limited thereto. The power line PL may correspond to the fourth power line PL4 described with reference to FIG. 5.

First to fourth dam members DM1, DM2, DM3, and DM4 may be further disposed in the non-display area NDA. The first to fourth dam members DM1, DM2, DM3, and DM4 may be disposed further outside the power line PL relative to the display area DA. For example, the power line PL may be disposed between the first to fourth dam members DM1, DM2, DM3, and DM4 and the display area DA.

The first dam member DM1 may at least partially overlap the power line PL in the third direction DR3. The first dam member DM1 may include a lower dam pattern disposed on the third interlayer insulating layer IL3 and an upper dam pattern disposed on the lower dam pattern.

The second dam member DM2 may be disposed outside the first dam member DM1. The second dam member DM2 may be spaced apart from the first dam member DM1. The second dam member DM2 may include a lower dam pattern disposed on the third interlayer insulating layer IL3 and an upper dam pattern disposed on the lower dam pattern.

The third dam member DM3 may be disposed outside the second dam member DM2. The third dam member DM3 may be spaced apart from the second dam member DM2. The third dam member DM3 may include a lower dam pattern disposed on the third interlayer insulating layer IL3 and an upper dam pattern disposed on the lower dam pattern.

The fourth dam member DM4 may be disposed outside the third dam member DM3. The fourth dam member DM4 may be spaced apart from the third dam member DM3. The fourth dam member DM4 may be disposed on the third interlayer insulating layer IL3.

The lower dam patterns of the first to third dam members DM1, DM2, and DM3 and the fourth dam member DM4 may be disposed on the same layer as the via layer VIA. The lower dam patterns of the first to third dam members DM1, DM2, and DM3 and the fourth dam member DM4 may include the same material as the via layer VIA. The lower dam patterns of the first to third dam members DM1, DM2, and DM3 and the fourth dam member DM4 may be formed concurrently (e.g., simultaneously) in the same process as the via layer VIA, but are not necessarily limited thereto.

In some embodiments, the heights of the first to fourth dam members DM1, DM2, DM3, and DM4 may be different from each other. For example, a height of the second dam member DM2 in the third direction DR3 may be greater than a height of the first dam member DM1 in the third direction DR3. A height of the third dam member DM3 in the third direction DR3 may be greater than the height of the second dam member DM2 in the third direction DR3. Accordingly, it is possible to effectively prevent or substantially impede organic substances from overflowing during the process of forming the encapsulation layer TFE, for example, the second encapsulation layer TFE2. A height of the fourth dam member DM4 in the third direction DR3 may be less than the height of the first dam member DM1 in the third direction DR3.

First and second pad electrodes PD1 and PD2 of a pad PD (see, e.g., FIG. 4) may be further disposed in the non-display area NDA. The first and second pad electrodes PD1 and PD2 may be disposed further outside the dam members DM1, DM2, DM3, and DM4 relative to the display area DA. The first pad electrode PD1 may be disposed on the third interlayer insulating layer IL3. The first pad electrode PD1 may be formed of a third conductive layer. The first pad electrode PD1 may be disposed on the same layer as the first terminal EL1 and/or the second terminal EL2. The first pad electrode PD1 may include the same or substantial material as the first terminal EL1 and/or the second terminal EL2. The first pad electrode PD1 may be formed concurrently (e.g., simultaneously) in the same process as the first terminal EL1 and/or the second terminal EL2, but is not limited thereto. The first pad electrode PD1 may be electrically connected to a wiring layer WL through a contact hole penetrating the third interlayer insulating layer IL3.

The wiring layer WL may be disposed between the second interlayer insulating layer IL2 and the third interlayer insulating layer IL3. The wiring layer WL may be formed of a second conductive layer. The wiring layer WL may be disposed on the same layer as the gate electrode GE. The wiring layer WL may include the same material as the gate electrode GE. The wiring layer WL may be formed concurrently (e.g., simultaneously) in the same process as the gate electrode GE, but is not necessarily limited thereto.

The second pad electrode PD2 may be disposed on the first pad electrode PD1. The second pad electrode PD2 may overlap the first pad electrode PD1 in the third direction DR3. The second pad electrode PD2 may be electrically connected to the first pad electrode PD1. The second pad electrode PD2 may be directly disposed on the first pad electrode PD1 and may be in contact with the first pad electrode PD1.

The bank BNK and/or the color filter layer CFL may be further disposed in the non-display area NDA. For example, the bank BNK may at least partially overlap the first dam member DM1 and/or the second dam member DM2 in the third direction DR3. The color filter layer CFL, for example, the third color filter CF3, may at least partially overlap the bank BNK in the non-display area NDA in the third direction DR3.

Subsequently, a manufacturing method of the display device according to the above-described embodiments will be described.

FIGS. 9 to 12 are cross-sectional views showing step-by-step processes of a method manufacturing of a display device according to some embodiments of the present disclosure. FIGS. 9 to 12 are cross-sectional views for explaining the manufacturing method of the display device of FIGS. 1 to 8, and are briefly shown and some symbols may be omitted for convenience of description.

Referring to FIG. 9, first, the trench TR may be formed on the first surface S1 of the substrate SUB. The trench TR may have a recessed shape from the first surface S1 of the substrate SUB. The trench TR may serve to form a pre-segmentation to reduce (e.g., minimize) the contact time of the etchant during the process of etching the substrate SUB. Accordingly, the substrate SUB can be easily cut and a decrease in the impact strength of the substrate SUB can be significantly reduced (e.g., minimized) at the same time.

The side surface S3 of the trench TR may have an inclination (e.g., be at a non-90 degree angle relative to the top surface of the substrate). The inclination angle formed between the side surface S3 and the second surface S2 of the trench TR may be about 70° to about 80°, but is not necessarily limited thereto. The width WT of the trench TR in the first direction DR1 may be about 8 μm to about 12 μm, but is not necessarily limited thereto. The depth DT of the trench TR in the third direction DR3 may be about 80 μm to about 100 μm, but is not necessarily limited thereto.

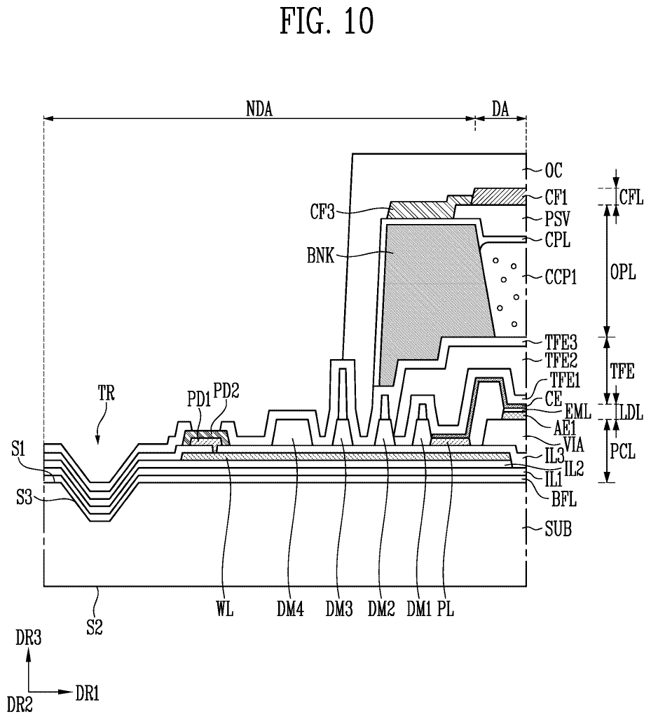

Referring to FIG. 10, and then the pixel circuit layer PCL, the light emitting element layer LDL, the encapsulation layer TFE, the optical layer OPL, the color filter layer CFL, and/or form the overcoat layer OC may be formed on the first surface S1 of the substrate SUB.

The pixel circuit layer PCL may be formed on the trench TR. For example, the buffer layer BFL, the first interlayer insulating layer IL1, the second interlayer insulating layer IL2, and/or the third interlayer insulating layer IL3 may be formed on the trench TR. The buffer layer BFL, the first interlayer insulating layer IL1, the second interlayer insulating layer IL2, and/or the third interlayer insulating layer IL3 may have an inclination on the side surface S3 of the trench TR.

The encapsulation layer TFE may be formed on the trench TR. For example, the third encapsulation layer TFE3 may be formed on the trench TR. The third encapsulation layer TFE3 may have an inclination on the side surface S3 of the trench TR. According to some embodiments, the first encapsulation layer TFE1 and/or the capping layer CPL may also be formed on the trench TR. In this case, the first encapsulation layer TFE1 and/or the capping layer CPL may have an inclination on the side surface S3 of the trench TR.

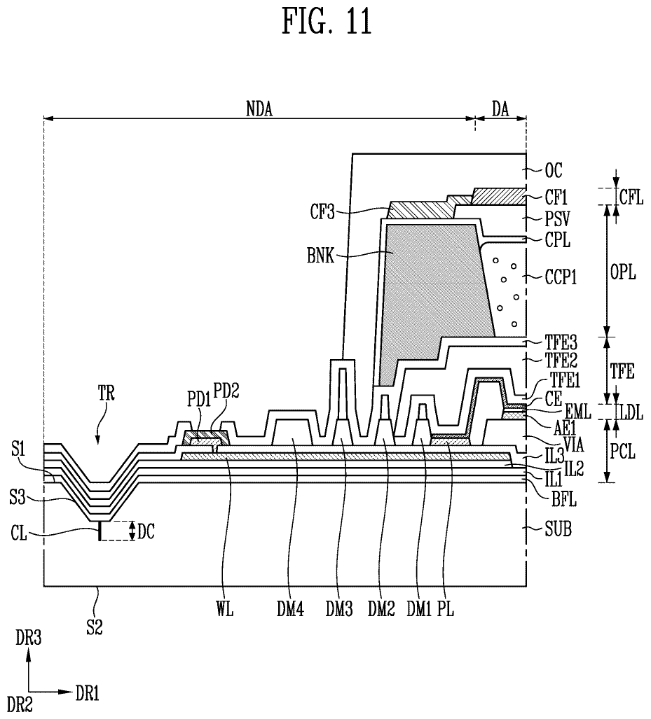

Referring to FIG. 11, a cutting line CL may be formed on the lower surface of the trench TR. The cutting line CL may be partially formed on the substrate SUB, but is not necessarily limited thereto. The depth DC of the cutting line CL in the third direction DR3 may be about 16 μm to about 20 μm, but is not necessarily limited thereto.

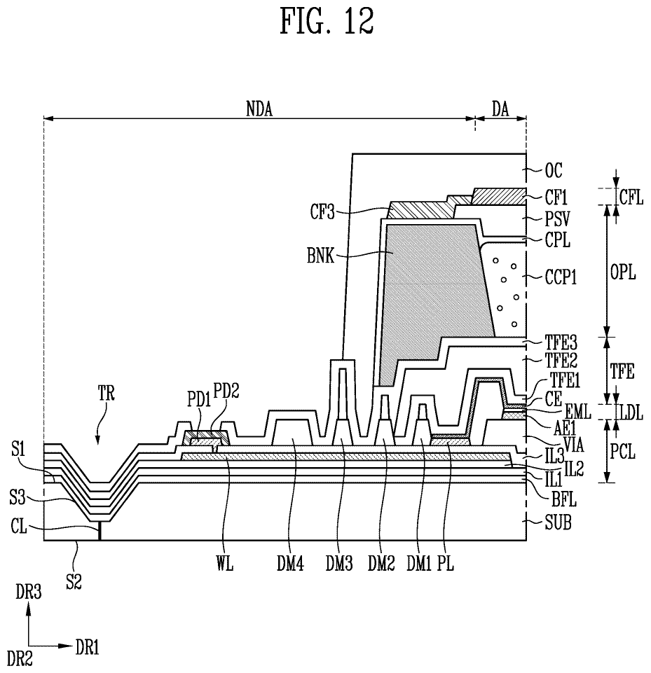

Referring to FIG. 12, the second surface S2 of the substrate SUB may be then etched. The second surface S2 of the substrate SUB may be etched to form a thinner thickness of the substrate SUB in the third direction DR3. The thickness of the substrate SUB in the third direction DR3 may be about 80 μm to about 100 μm, but is not necessarily limited thereto.

In the process of etching the second surface S2 of the substrate SUB, the substrate SUB may be cut by etching along the cutting line CL. Accordingly, as shown in FIG. 8, the side surface S3 of the trench TR may form the side surface that is an outer edge of the substrate SUB.

According to the above-described method, when the trench TR is formed on the substrate SUB and the cutting line CL is formed, and then the substrate SUB is etched and cut, the contact time of the etchant can be reduced (e.g., minimized) during the process of etching the substrate SUB. Therefore, as described previously, the impact strength of the substrate SUB can be improved.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate comprising a first surface, a second surface, and a side surface between the first surface and the second surface;
a pixel circuit layer on the first surface and the side surface of the substrate and comprising a transistor; and
a light emitting element on the pixel circuit layer and electrically connected to the transistor,
wherein the side surface of the substrate has an inclination.

2. The display device of claim 1, wherein the transistor comprises a first conductive layer, a second conductive layer, and an insulating layer between the first conductive layer and the second conductive layer, and
wherein the insulating layer is on the side surface of the substrate.

3. The display device of claim 2, wherein the insulating layer has an inclination on the side surface of the substrate.

4. The display device of claim 1, further comprising:
an encapsulation layer on the light emitting element,
wherein the encapsulation layer is on the side surface of the substrate.

5. The display device of claim 4, wherein the encapsulation layer has an inclination on the side surface of the substrate.

6. The display device of claim 4, further comprising:
a bank on the encapsulation layer.

7. The display device of claim 6, further comprising:
a light conversion pattern within an opening of the bank.

8. The display device of claim 7, wherein the light conversion pattern is directly on the encapsulation layer.

9. The display device of claim 7, further comprising:
a color filter on the light conversion pattern.

10. The display device of claim 1, further comprising:
a rotating member configured to wind and unfold the substrate.

11. The display device of claim 10, further comprising:
a housing configured to accommodate the substrate and the rotating member.

12. A manufacturing method of a display device comprising:
forming a trench on a first surface of a substrate;
forming a pixel circuit layer on the trench;
forming a light emitting element on the pixel circuit layer;
forming a cutting line on a lower surface of the trench; and
etching a second surface of the substrate to reduce a thickness of the substrate.

13. The manufacturing method of claim 12, wherein the pixel circuit layer has an inclination on a side surface of the trench.

14. The manufacturing method of claim 12, further comprising:
forming an encapsulation layer on the light emitting element,
wherein the encapsulation layer is formed on the trench.

15. The manufacturing method of claim 14, wherein the encapsulation layer has an inclination on a side surface of the trench.

16. The manufacturing method of claim 14, further comprising:
forming a light conversion pattern on the encapsulation layer.

17. The manufacturing method of claim 16, further comprising:
forming a color filter on the light conversion pattern.

18. The manufacturing method of claim 12, wherein a depth of the trench is 80 μm to 100 μm.

19. The manufacturing method of claim 12, wherein a depth of the cutting line is 16 μm to 20 μm.

20. The manufacturing method of claim 12, wherein the substrate is cut along the cutting line in the etching the second surface of the substrate.
